(19) United States
(12) Patent Application Publication
(10) Pub. No.: US 2007/0007541 A1
(43) Pub. Date: Jan. 11, 2007

(54) White light emitting device

(75) Inventors: Min Ho Kim, Suwon (KR); Kyeong Ik Min, Seoul (KR); Masayoshi Koike, Suwon (KR)

Correspondence Address: VOLPE AND KOENIG, P.C., UNITED PLAZA, SUITE 1600, 30 SOUTH 17TH STREET, PHILADELPHIA, PA, 19103, US

(73) Assignee: Samsung Electro-Mechanics Co., Ltd., Suwon (KR)

(21) Appl. No.: 11/331,751

(22) Filed: Jan. 13, 2006

(30) Foreign Application Priority Data
Jul. 7, 2005 (KR) 10-2005-61101

(51) Int. Cl. H01L 33/00

(52) U.S. Cl. 257/94

(57) ABSTRACT

The invention relates to a nitride light emitting device including first and second conductivity type nitride layers and a plurality of active regions emitting light of different wavelength. The active regions are sequentially formed between the first and the second conductivity type nitride layers. The active regions include at least one first active region having a plurality of first quantum barrier layers and quantum well layers, and a second active region emitting light of a wavelength larger than that of the first active region. The second active region has a plurality of second quantum barrier layers and at least one discontinuous quantum well structure formed between the plurality of second quantum barrier layers. The discontinuous quantum well structure comprises a plurality of quantum dots or crystallites.

### CLAIM OF PRIORITY

This application claims the benefit of Korean Patent Application No. 2005-61101 filed on Jul. 7, 2005, in the Korean Intellectual Property Office, the disclosure of which is incorporated herein by reference.

### BACKGROUND OF THE INVENTION

1. Field of the Invention

The present invention relates to a white light emitting device. More particularly, the present invention relates to a monolithic white light emitting device which has at least 2 active regions emitting light of different wavelength configured as a single device, and a manufacturing thereof.

2. Description of the Related Art

In general, a white light emitting device employing Light Emitting Diode (LED) ensures high brightness and high efficiency, thus widely used as a back light for lighting apparatus or display apparatus.

Broadly known methods for configuring the white light emitting device include simple combination of blue, red and green LEDs manufactured as a separate LED and use of fluorescent substance. Combination of each differently colored LED on the same printed circuit board requires complicated driving circuit therefore, leading to an attendant drawback of difficulty in miniaturization. Therefore, a manufacturing method of white light emitting device via florescent substance is typically used.

Conventional manufacturing methods for the white light emitting device via florescent substance include use of a blue light emitting device and use of an ultraviolet light emitting device. For example, in case of using the blue light emitting device, YAG florescent substance is used to convert blue light into white light. That is, blue wavelength generated from blue LED excites Yittrium Aluminum Garnet (YAG) to produce white light eventually.

However, the conventional methods as just described have a limit in obtaining good colors since florescent powder adversely affects device properties, and light efficiency and color compensating index diminish in exciting florescent substance.

In an attempt to solve such problems, a study is actively under way regarding the monolithic white light emitting device having a plurality of active regions emitting light of different wavelength without florescent substance. As one type of the monolithic white light emitting device, U.S. Pat. No. 5,684,309 (patented on Nov. 4, 1997, assigned to North Carolina State University) discloses a white light emitting device as shown in FIG. 1.

As shown in FIG. 1, the white light emitting device 10 comprises a first conductivity nitride layer 13 and a second nitride layer 18 formed on a substrate 11 having a buffer layer 12 interposed between the substrate 11 and the first conductivity nitride layer 13. Between the first and second conductivity type nitride layers 13, 18, there are first, second, and third active layers 15, 16, 17 emitting light of 3 different wavelength, and barrier layers 14a,14b,14c, 14d. Also, on the first and second conductive nitride layers 13, 18, first and second electrodes 19a,19b are provided.

In a structure shown in FIG. 1, the first to third active regions 15, 16, 17, for example, have a composition expressed by InₓGal₁₋ₓN (x is a variable) to emit blue, green and red lights respectively. Blue, green and red lights obtained from each active region 15,16,17 are combined to produce desired white light finally.

But the white light emitting device disclosed in the cited reference does not have high light emitting efficiency and the three colors for obtaining white light are not evenly distributable. That is because as shown in FIG. 2, the active region 17 emitting red light has energy band gap Eg3 that is very lower than energy band gaps Eg1,Eg2 of the active regions 15, 16 emitting blue and green lights. For example, energy band gaps Eg1,Eg2 of the active regions 15, 16 emitting blue and green lights are about 2.7 eV, 2.4 eV respectively, while energy band gap Eg3 of the active region 17 emitting red light is just about 1.8 eV, a relatively low level.

Likewise, low energy band gap Eg3 of long wavelength active region 17 results in carrier localization because carriers provided by the second conductivity type nitride layer 18 do not pass the active region 17 emitting red light. As a result, most carriers are constrained in the active region 17 emitting red light to be converted into light, thus less likely to reach blue and green active regions 15, 16. This is aggravated in case where the second conductivity type nitride layer 18 is p-type nitride layer, because carriers constrained in the active region 17 emitting red light have lower mobility than electrons.

The conventional white light emitting device has significantly low recombination efficiency of short wavelength active region due to constraint of carriers by long wavelength active region. Therefore white light cannot be obtained through proper color distribution.

### SUMMARY OF THE INVENTION

The present invention has been made to solve the foregoing problems of the prior art and it is therefore an object of the present invention to provide a novel monolithic light emitting device which enhances recombination efficiency of short wavelength active region by realizing long wavelength active region out of a plurality of active regions emitting different wavelength with a discontinuous structure such as quantum dots or quantum crystallites, instead of a continuous layer structure.

According to an aspect of the invention for realizing the object, there is provided a semiconductor light emitting device comprising first and second conductivity type nitride layers; and a plurality of active regions emitting light of different wavelength, and sequentially formed between the first and the second conductivity type nitride layers, wherein the active regions include at least one first active region having a plurality of first quantum barrier layers and quantum well layers, and a second active region emitting light of a wavelength larger than that of the first active region, and wherein the second active region has a plurality of second quantum barrier layers and at least one discontinuous quantum well structure formed between the plurality of second quantum barrier layers, the discontinuous quantum well structure comprising a plurality of quantum dots or crystallites respectively.

According to present invention, the second active region emitting long wavelength which induces constraint of carriers has the discontinuous structure comprising quantum dots or crystallites. This substantially enhances efficiency of carriers injection provided to the first active region emitting short wavelength.

The plurality of quantum dots or crystallites constituting the discontinuous quantum well structure preferably have a total area that is 20 to 75% of the total area of a surface of a corresponding second quantum barrier layer. If the total area of the quantum well structure is less than 20%, sufficient brightness cannot be ensured, while if it is greater than 75%, recombination efficiency of the first active region emitting short wavelength cannot be boosted sufficiently.

Preferably, the second active region comprises at least 4 quantum barrier layers and at least 3 discontinuous quantum well structures formed between at least 4 quantum barrier layers, each of the discontinuous quantum well structure comprising a plurality of quantum dots or crystallites formed between at least 4 quantum barrier layers, respectively. Thereby sufficient brightness can be ensured through the discontinuous quantum well structure.

In one embodiment of the present invention, the first active region includes 2 active layers, one emitting light of about 450 to 475 nm wavelength, and the other emitting light of about 510 to 535 nm. The second active region is adapted to emit light of about 600 to 635 nm wavelength. That is, the two active layers of the first active region emit blue and green light of wavelength, respectively, and the second active region is adapted to emit red light, thus producing white light input in the end.

In other embodiment of the present invention, the first active region may be adapted to emit light of about 450 to 475 nm wavelength, and the second active region may be adapted to emit light of about 550 to 600 nm wavelength. That is, the first active region is adapted to emit green-biased blue light of wavelength, and the second active region is adapted to emit yellow light of wavelength, thus producing white light finally.

According to the present invention, the first active region has a composition expressed by Inₓ₁Ga₁₋ₓ₁N, wherein 0≦x₁≦1. As shown in one embodiment of the present invention, in case of forming 2 active layers, In contents (x₁) can be varied adequately to provide active layers emitting desired light of wavelength.

Also, the second active region has a composition expressed by Inₓ₂Ga₁₋ₓ₂N(0<x₂≦1). In this case, to solve crystalline degradation and wavelength change resulting from increase in In contents, the discontinuous quantum well structure of the second active region preferably has a composition expressed by Al_{y}In_{z}Ga_{1-(y+z)}N) or (AlᵥGa₁₋ᵥ)ᵤIn₁₋ᵤP, wherein 0<y<1, 0<z<1, 0≦v≦1, and 0≦u≦1.

In case where the first conductivity type nitride semiconductor layer comprises an n-type nitride semiconductor layer, and the second conductivity nitride layer comprises a p-type nitride semiconductor layer, the second active region is placed adjacent to the second conductivity type nitride semiconductor layer. Furthermore, in case where the first active region comprises a plurality of layers emitting light of different wavelength, the first and second active regions are arranged in such a fashion that an active region or layer having a longer wavelength is placed more adjacent to the second conductivity type layer.

Especially, in case where the second active region has a composition expressed by Al_{y}In_{z}Ga_{1-(y+z)}N or (AlᵥGa₁₋v)ᵤIn₁₋ᵤP, wherein 0<y<1, 0<z<1, 0≦v≦1, and 0≦u≦1, preferably growth temperature by deposition procedure should be considered to form the second active region later than the first active region.

### BRIEF DESCRIPTION OF THE DRAWINGS

The above and other objects, features and other advantages of the present invention will be more clearly understood from the following detailed description taken in conjunction with the accompanying drawings, in which:

FIG. 1 is a sectional view of a conventional white light emitting device;

FIG. 2 is a diagram illustrating energy band for an active region of the conventional white light emitting device;

FIG. 3 is a sectional view of a white light emitting device according to one embodiment of the invention;

FIG. 4a and 4b are diagrams of vertical view showing energy band of an active region of the white light emitting device;

FIG. 5 is a perspective view illustrating surface of a discontinuous quantum structure employed in an active region according to the invention;

FIG. 6 is a sectional view illustrating the white light emitting device according to another embodiment of the invention.

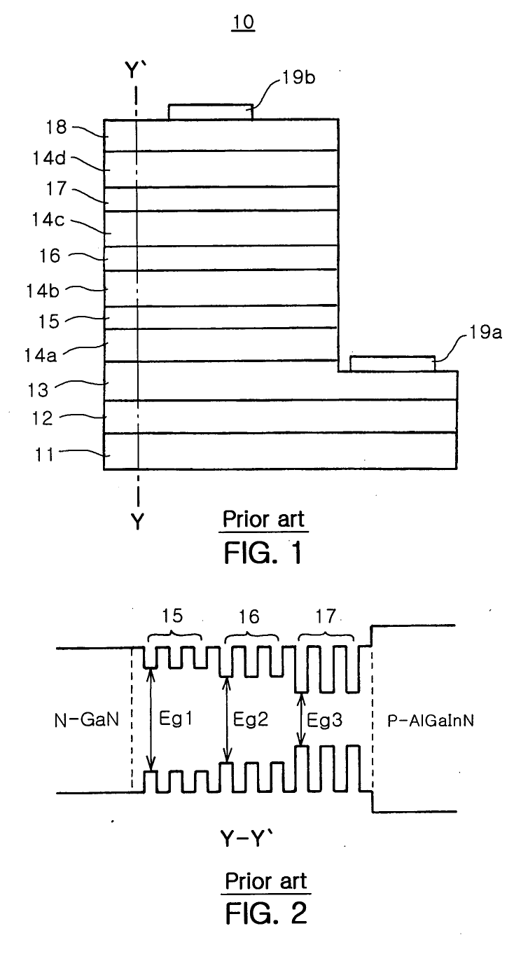

### DETAILED DESCRIPTION OF THE PREFERRED EMBODIMENT

Preferred embodiments of the present invention will now be described in detail with reference to the accompanying drawings.

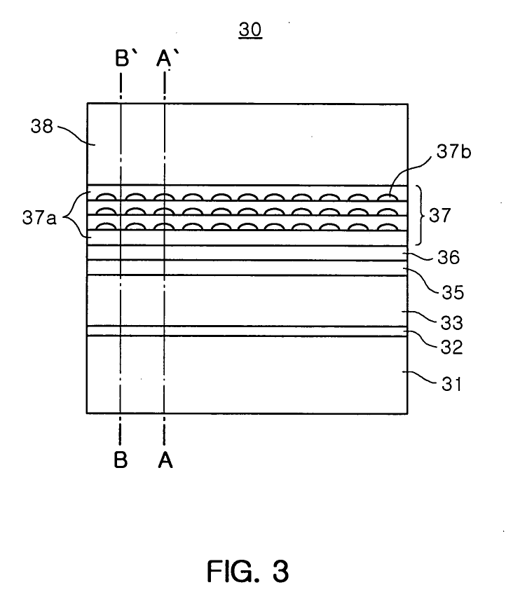

FIG. 3 is a sectional view of a white light emitting device of the invention.

Referring to FIG. 3, the white light emitting device 30 includes a first conductivity type nitride layer 33 and a second conductivity type nitride layer 38 formed on a substrate 31 having a buffer layer 32 interposed between the substrate 31 and the first conductivity type nitride layer 33, and active regions 35,36,37 emitting blue, green and red wavelength lights between the first and second conductivity type nitride layers 33, 38.

The blue and green active regions 35,36 include typical continuous layers, and may include a multiple quantum well structure having a plurality of quantum well layers and quantum barrier layers (not illustrated). Also, the blue and green active regions 35,36 may have quantum well layers, one emitting light of about 450 to 475 nm wavelength, and the other emitting light of 510 to 535 nm wavelength. Preferably, the blue and green active regions 35, 36 have a composition expressed by Inₓ₁Ga₁₋ₓ₁N having different indium contents (x₁), wherein 0≦x₁≦1.

According to the embodiment of the present invention, an active region 37 emitting red light includes 4 quantum barrier layers 37a and 3 discontinuous quantum well structures 37b made of a plurality of quantum dots or crystallites and formed between the 4 quantum barrier layers, respectively. In this specification, the discontinuous quantum well structure means a structure having a plurality of quantum dots or crystallites arranged across a total area, excluding quantum well layers having a complete layer structure continuously grown across a surface. The quantum dots or crystallites 37b on a plane are sandwiched by two barrier layers 37a of the active region 37 emitting red light. That is, a barrier layer 37a provides a surface where quantum dots or crystallites 37b are grown and serves as a capping layer for underlying quantum dots or crystallites 37b.

The discontinuous quantum well structure 37b, or the plurality of quantum dots or crystallites of the invention provides quantum wells to emit red light. That is, the structure 37b is made of semiconductor material emitting light of about 600 to 635 nm wavelength. The barrier layer 37a of the active region 37 emitting red light and the discontinuous quantum well structure 37b may have a composition expressed by Inₓ₂Ga₁₋ₓ₂N having different compositions, wherein 0<x₂≦1. For example, the active region 37 emitting red light may be formed of GaN quantum barrier layers and In_{0.7}Ga_{0.3}N quantum dots. However, great portions of In contents degrade crystallinity and cause undesired wavelength change due to phase separation. Therefore, the discontinuous quantum well structure 37b for emitting red light should preferably have a composition expressed by Al_{y}In_{z}Ga_{1-(y+z)}N or (AlᵥGa₁₋ᵥ)ᵤIn₁₋ᵤP, wherein 0<y≦1, 0<z<1, 0≦v≦1, and 0≦u≦1.

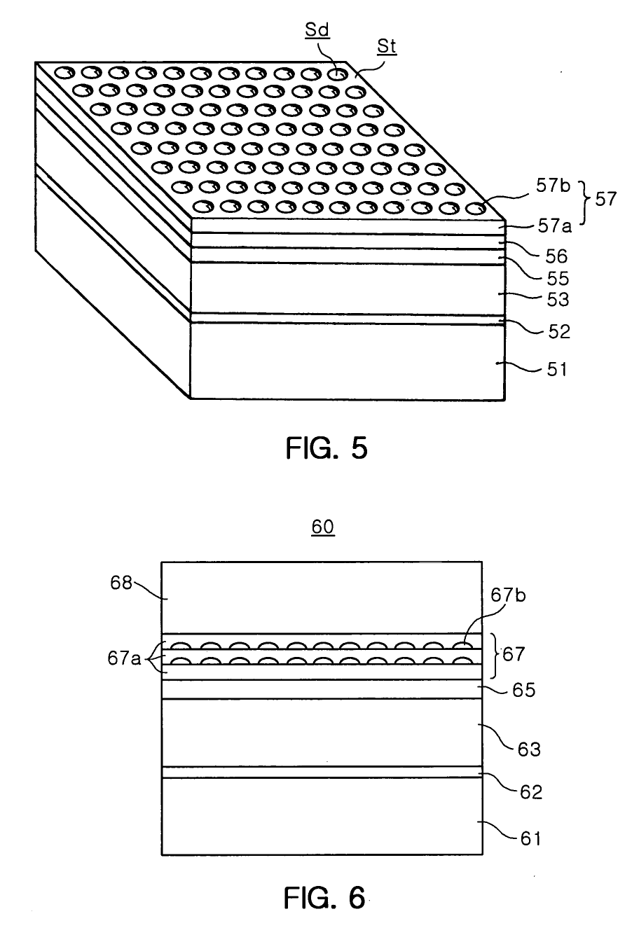

The first conductivity type nitride semiconductor layer 33 may be n-type nitride semiconductor layer and the second conductivity type nitride semiconductor layer 38 may be p-type nitride semiconductor layer. In this case, as shown in this embodiment of the invention, the active region emitting red light 37 is preferably placed adjacent to the second conductivity type nitride semiconductor layer 38. Also, blue and green active regions 35, 36 are preferably arranged in such a fashion that any active region having a longer wavelength is placed more adjacent to the second conductivity type nitride layer 38. This is because of process conditions such as growth temperature and will be explained in greater detail in FIG. 5.

The discontinuous quantum well structure 37b comprising quantum dots or crystallite according to the invention may directly provide the green active region 36 with carriers (e.g. holes) injected from the second conductivity type nitride semiconductor layer 38.

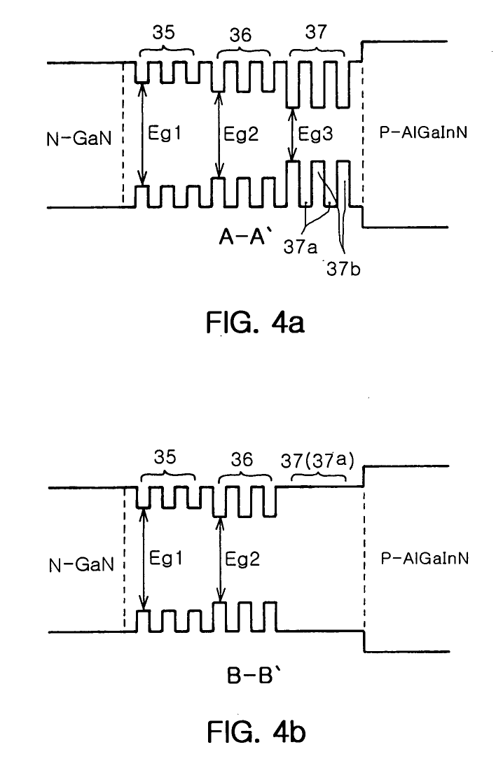

That is, in a carrier path A-A′ where carriers pass areas having quantum dots or crystallites 37b as shown in FIG. 4a, an energy band similar to a conventional one as shown in FIG. 2 is formed. In this case, carriers injected from the first conductivity type nitride semiconductor layer 33 pass through the quantum well structure 37b of the active region emitting red light 37, thereby inducing adequate red light emission,

Meanwhile, in a carrier path B-B′ where carriers pass areas having no quantum dots or crystallites 37b as shown in FIG. 4b, carriers injected from the first conductivity type nitride semiconductor layer 33 pass only GaN-like quantum barrier layers 37a without quantum well structure in the active region emitting red light. This reduces likelihood that carriers will be constrained in the quantum well structure 37b of the long wavelength active region emitting red light 37, resultantly increasing carrier doping efficiency in the short wavelength active region 35, 36 that emits green or blue light.

The active region 37 emitting red light still has lower light emission efficiency than continuous active regions 35, 36 emitting blue or green light due to its discontinuous structure. To solve this problem, as shown in this embodiment of the invention, the active layer emitting red light 37 preferably includes at least 4 quantum barrier layers 37a and at least 3 discontinuous quantum well structures 37b.

FIG. 5 is a perspective view illustrating a surface of the discontinuous quantum structure employed in the first active region. FIG. 5 may be understood as illustrating a state in which quantum dots are formed in a manufacturing process of a light emitting device similar to FIG. 4.

As in FIG. 5, a buffer layer 52, a first conductivity type nitride semiconductor layer 53, an active region emitting blue light 55 and an active region emitting green light 56 are sequentially formed on a substrate 51, and then an active region emitting red light 57 is formed thereon. The active region emitting red light 57 is formed via a process of forming a discontinuous quantum well structure 57b such as quantum barrier layer 57a, quantum dots or crystallites.

The discontinuous quantum well structure 57b, as set forth above, has a composition expressed by Inₓ₂Ga₁₋ₓ₂N, wherein 0<x₂≦1, but preferably has a composition expressed by Al_{y}In_{z}Ga_{1-(y+z)}N or (AlᵥGa₁₋ᵥ)ᵤIn₁₋ᵤP, wherein 0<y<1, 0<z<1, 0≦v≦1, and 0≦u≦1. The discontinuous quantum well structure 57b can be easily formed through notified process by those skilled in the art.

Further, the long wavelength active region, or active region 57 emitting red light, as shown in this embodiment of the invention, is preferably formed after forming active regions 55, 56 emitting other wavelength lights. Especially in case of forming the AlInGaN discontinuous quantum well structure 57b, growth temperature should be considered to form the structure 57b later than other active regions 55,56. Accordingly since generally p-type nitride semiconductor layer is placed top, the active region 57 emitting red light in the light emitting device is adjacent to the p-type nitride semiconductor layer, and the active regions emitting blue and green lights 55, 56 are preferably arranged in such a fashion that any active layer having a longer wavelength is placed more adjacent to the p-type nitride semiconductor layer.

According to the invention, in the red active region 57 having the discontinuous quantum well structure 57b, it is preferable that greater portions of the area do not have any discontinuous quantum well structure to alleviate constraints of carriers. But if the discontinuous quantum well structure does not exist in too small portions of the area, light emission efficiency of the short wavelength active region 57 emitting red light can not be sufficiently ensured. Therefore preferably, the plurality of quantum dots or crystallites have a total area ΣSd that is 20 to 75% of the total area ST of a top surface of a corresponding second quantum barrier layer. The area having the plurality of quantum dots or crystallites can be obtained by controlling temperature and time during growth process and thus properly controlling size and density of quantum dots or crystallites.

The embodiment as described above illustrates 3 active regions emitting light of different wavelength but the present invention is not limited thereto. That is, the scope of the invention includes a light emitting device having 2 active regions or at least 4 active regions. For example, the invention, as shown in FIG. 6, can be configured as a light emitting device having 2 active regions emitting light of different wavelength.

Referring to FIG. 6, the white light emitting device 60, similar to FIG. 3, includes a first conductivity type nitride layer 63 and a second conductivity type nitride layer 68 formed on a substrate 61 having a buffer layer 62 interposed between the substrate 61 and the first conductivity type nitride layer 63, and first, and second active regions 65, 67 emitting light of different wavelength are formed between the first and second conductivity type nitride layers 63,68. To emit white light, the first active region 65 is adapted to emit light of about 450 to 475 nm wavelength, and the second active region 67 is adapted to emit light of about 550 to 600 nm wavelength.

The first active region 65 is a typical continuous layer and has a composition expressed by Inₓ₁Ga₁₋ₓ₁N, wherein 0≦x₁≦1. Also, the first active region 65 has a multiple quantum well structure made of a plurality of quantum well layers and quantum barrier layers (not illustrated) . Meanwhile the second active region 67 may include 3 quantum barrier layers 67a and 2 discontinuous quantum well structures 67b made of a plurality of quantum dots or crystallites and formed between the 3 quantum barrier layers 67a, respectively. In this case, the barrier layer 67a of the second active region 67 and discontinuous quantum well structure 67b may have a composition expressed by Inₓ₂Ga₁₋ₓ₂N having different compositions, wherein 0<x₂<1. Preferably, the quantum well structure 67b has a composition expressed by Al_{y}In_{z}Ga_{1-(y+z)}N or (AlᵥGa₁₋ᵥ)ᵤIn₁₋ᵤP, wherein 0<y<1, 0<z<1, 0≦v≦1, and 0≦u≦1.

Likewise, with respect to 2 active regions emitting light of different wavelength, the discontinuous quantum well structure can be employed in the second active region emitting long wavelength. Thereby constraints of carriers, which occur in the second active region, are prevented and light emitting efficiency of the first active region is enhanced. This results in adequate color distribution of the first and second active regions to combine into white light.

The present invention provides a method for employing the discontinuous quantum well structure in the long wavelength active regions to reduce carrier localization occurring in the long wavelength active region with respect to a conventional structure of a plurality of continuous active regions. Therefore, as stated above, no limit is placed on the number of the active regions or the white light emitting device. In the semiconductor light emitting device for creating specified light by combining at least 2 active regions emitting light of different wavelength, the present invention includes all types of light emitting devices which select only the long wavelength active region causing carrier localization to replace with the discontinuous quantum well structure such as quantum dots or crystallites.

As stated above, according to the present invention, there is provided a semiconductor light emitting device capable of increasing recombination efficiency of the short wavelength active region. This is made possible by selecting only the long wavelength active region causing carrier localization out of at least 2 active regions emitting light of different wavelength to replace with the discontinuous quantum well structure such as quantum dots or crystallites. In more particular, the present invention enables relatively even color distribution in the active regions of different wavelength and thus can be used to manufacture a monolithic white light emitting device with high efficiency by combining specified wavelength lights.

While the present invention has been shown and described in connection with the preferred embodiments, it will be apparent to those skilled in the art that modifications and variations can be made without departing from the spirit and scope of the invention as defined by the appended claims.

What is claimed is:

1. A nitride light emitting device comprising:
first and second conductivity type nitride layers; and a plurality of active regions emitting light of different wavelength, and sequentially formed between the first and the second conductivity type nitride layers,
wherein the active regions include at least one first active region having a plurality of first quantum barrier layers and first quantum well layers, and a second active region emitting light of a wavelength larger than that of the first active region, and
wherein the second active region has a plurality of second quantum barrier layers and at least one discontinuous quantum well structure formed between the plurality of second quantum barrier layers, the discontinuous quantum well structure comprising a plurality of quantum dots or crystallites respectively.

2. The semiconductor light emitting device according to claim 1, wherein the plurality of quantum dots or crystallites have a total area that is 20 to 75% of the total area of a top surface of a corresponding second quantum barrier layer.

3. The semiconductor light emitting device according to claim 1, wherein the second active region comprises at least 4 quantum barrier layers and at least 3 discontinuous quantum well structures formed between the at least 4 quantum barrier layers, each of the discontinuous quantum well structures comprising a plurality of quantum dots or crystallites formed between the at least 4 quantum barrier layers, respectively.

4. The semiconductor light emitting device according to claim 1, wherein the first active region is adapted to emit light of about 450 to 475 nm wavelength, and the second active region is adapted to emit light of about 550 to 600 nm wavelength.

5. The semiconductor light emitting device according to claim 1, wherein the first active region includes 2 active layers, one emitting light of about 450 to 475 nm wavelength, and the other emitting light of about 510 to 535 nm wavelength, and wherein the second active region is adapted to emit light of about 600 to 635 nm wavelength.

6. The semiconductor light emitting device according to claim 1, wherein the first conductivity type nitride layer comprises an n-type nitride semiconductor layer, and the second conductivity type nitride layer comprises a p-type nitride semiconductor layer, and wherein the second active region is placed adjacent to the second conductivity type nitride layer.

7. The semiconductor light emitting device according to claim 1, wherein the first conductivity type nitride semiconductor layer comprises an n-type nitride semiconductor layer, and the second conductivity nitride layer comprises a p-type nitride semiconductor layer, the first active region comprises a plurality of layers emitting light of different wavelength, and wherein the first and second active regions are arranged in such a fashion that an active region or layer having a longer wavelength is placed more adjacent to the second conductivity type nitride layer.

8. The semiconductor light emitting device according to 1, wherein the first active region has a composition expressed by Inₓ₁Ga₁₋ₓ₁N, wherein 0≦x₁≦1.

9. The semiconductor light emitting device according to claim 1, wherein the second active region has a composition expressed by Inₓ₂Ga₁₋ₓ₂N, wherein 0<x₂≦1.

10. The semiconductor light emitting device according to claim 9, wherein the first conductivity type nitride semiconductor layer comprises an n-type nitride semiconductor layer, and the second conductivity nitride layer comprises a p-type nitride semiconductor layer, the first active region comprises a plurality of layers emitting light of different wavelength, and wherein the first and second active regions are arranged in such a fashion that an active region or layer having a longer wavelength is placed more adjacent to the second conductivity type nitride layer.

11. The semiconductor light emitting device according to claim 9, wherein the discontinuous quantum well structure of the second active region has a composition expressed by Al_{y}In_{z}Ga_{1-(y+z)}N or (AlᵥGa₁₋ᵥ)ᵤIn₁₋ᵤP, wherein 0<y<1, 0<z<1, 0≦v≦1, and 0≦u≦1.

12. The semiconductor light emitting device according to claim 9, wherein the first conductivity type nitride layer comprises an n-type nitride semiconductor layer, and the second conductivity type nitride layer comprises a p-type nitride semiconductor layer, and wherein the second active region is placed adjacent to the second conductivity type nitride layer.
